(19) United States
(12) Patent Application Publication
(10) Pub. No.: US 2009/0254213 A1
(43) Pub. Date: Oct. 8, 2009

(54) Mounting device for a chip component

(75) Inventors: Takaaki Domon, Akita (JP); Toshiyuki Nagatsuka, Narashino (JP); Toyotaka Kobayashi, Yuri Honjo (JP); Yushi Ogasawara, Yuri Honjo (JP)

Correspondence Address: OLIFF & BERRIDGE, PLC, P.O. BOX 320850, ALEXANDRIA, VA, 22320-4850, US

(73) Assignee: TDK CORPORATION, TOKYO (JP)

(21) Appl. No.: 12/379,165

(22) Filed: Feb. 13, 2009

(30) Foreign Application Priority Data
Mar. 28, 2008 (JP) 2008-087770

(51) Int. Cl. H01L 21/67

(52) U.S. Cl. 700/228

(57) ABSTRACT

The present invention provides a mounting device for a chip component, allowing short operating time for mounting a chip component after cutting, and capable of reliably mounting only an undamaged, non-defective chip component. The mounting device comprises carriers 10, 16 and 24, which transport a chip component 6a, peeled from a holding sheet 4 for holding cut individual chip components 6a, to a mounting substrate 20, and mount the chip component 6a thereon. The carriers 16 and 24 are provided with measuring terminals 18 and 26 for measuring electric properties of the chip component 6a during transporting. A control circuit is provided with the mounting device for controlling the carriers 16 and 24 so as to mount the chip component 6a on the mounting substrate 20 only when a measurement of the chip component 6a determined through measuring terminals 18 and 26 satisfies mountable conditions.

### BACKGROUND OF THE INVENTION

1. Field of the Invention

The present invention relates to a mounting device for a chip component, more particularly, a mounting device for a chip component allowing to easily prevent from mounting of a defective chip component found immediately before mounting the same on a substrate.

2. Description of the Related Art

When a wafer held on a holding sheet such as adhesive sheet of a wafer table is subject to die cutting and the obtained semiconductor bear chip components are mounted on a mounting substrate, the chip components are conventionally mounted without testing every chip component. Alternatively, the chip components subsequent to cutting on the holding sheet may be subject to individually testing, followed by mounting only the chip components determined as non-defective in the test.

However, when mounting chip components after peeling from the holding sheet such as adhesive sheet and transporting, the chip components may be damaged by static electricity due to peeling the same from the holding sheet, by colliding force due to ejector pin, etc. In such cases, damaged chip components may also be subject to mounting, and determined as defective in a test after mounting.

Note that as a mounting device for a mounting chip component such as an IC chip, for example, a device disclosed in Publication of Japanese utility model application H02-120900 is known. In this device, electric properties of chip components kept in a tape carrier are measured and examined before mounting.

However, in such a mounting device, IC chip determined as non-defective after the measurements may be damaged when taking out from the tape carrier due to static electricity, etc., and there still remains a possibility that the damaged IC chip is mounted.

Then, chip components peeled from a holding sheet such as an adhesive sheet, or chip components taken out from a tape carrier may be gather in one place prior to mounting for testing, and only those determined as non-defective may be subject to mounting. However, in this method, the tests require fair amount of time, which results in a problem that operating time from wafer cutting step to mounting step takes long.

### SUMMARY OF THE INVENTION

The present invention is made reflecting this situation, and has a purpose to provide a mounting device for a chip component, allowing short operating time for mounting a chip component after cutting and reliable of mounting only an undamaged, non-defective chip component.

To achieve the above purpose, a mounting device for a chip component according to the present invention comprises

a carrier for transporting said chip component, removed from a holding part which holds each of cut chip components, to a mounting substrate to mount the same,

a measuring terminal, provided with at least a part of said carrier, for measuring electric properties of said chip component during transporting,

a control means for controlling said carrier so as to mount said chip component on said mounting substrate only when a measurement of said chip component determined through said measuring terminal satisfies mountable conditions.

In the mounting device for a chip component according to the present invention, tests are performed during transportation by the carrier, resulting in short operating time for mounting a chip component after cutting. Also, a chip component, removed from a holding part such as a holding sheet, is tested during transportation, so that it is possible to reliably distinguish a chip component damaged due to peeling. It is also possible to eliminate defective chip components without satisfying mountable conditions during transportation, so that only undamaged, good-quality chip components may be reliably mounted.

Preferably, said carrier comprises a pick-up head for receiving said chip component removed from said holding part; and a mounting head for mounding said chip component on said mounting substrate. In this case, receiving operation by the pick-up head and mounting operation by the mounting head can be concurrently processed, so that operating time can be further shortened.

Preferably, said carrier further comprises a carrier table for transporting said chip component, received on said pick-up head, to said mounting head. Said measuring terminal may be provided with at least one of said mounting head and said carrier table. In this case, receiving operation by the pick-up head, mounting operation by the mounting head, and transporting operation by the carrier table can be concurrently processed, and a measurement for testing can be performed during the mounting operation or transporting operation.

Alternatively, said carrier may further comprise a stationary table for temporarily placing said chip component received on said pick-up head. In this case, said measuring terminal may be provided with at least one of said mounting head and said stationary table. In this case, a measurement for testing can be performed during the mounting operation or during temporarily placing on the stationary table.

Preferably, said holding part is a holding sheet for holding individual chip components, and may further comprise a peel off means for peeling said chip component from said holding sheet.

The holding sheet for holding said chip component is attached on a wafer table, and said peel off means may be an ejector pin which is inserted in an opening formed on said wafer table.

Preferably, a cutting means is placed on said wafer table, and said chip component can be obtained by cutting a wafer placed on said holding sheet and wafer table. In this case, it is possible to shorten operating time from cutting wafer to mounting a chip component.

Preferably, said carrier contacting with said chip component is grounded. By grounding the carrier, no static electricity is stored between the carrier and the chip component, so that it is possible to prevent damage on the chip component due to static electricity.

### DESCRIPTION OF THE PREFERRED EMBODIMENTS

Hereinafter, the present invention will be described based on an embodiment shown in drawings.

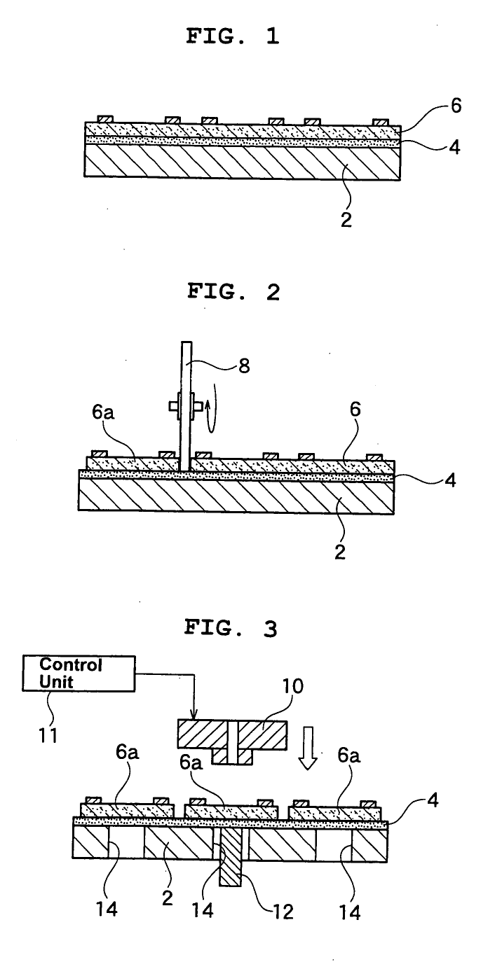

FIG. 1 to FIG. 16 are diagrams showing processes from wafer cutting to mounting using a mounting device for a chip component according to one embodiment of the present invention.

FIG. 1 is a cross-sectional view showing a wafer mounting process using a mounting device for a chip component according to one embodiment of the present invention.

FIG. 2 is a cross-sectional view showing the continuous step of the wafer mounting process from that of FIG. 1.

FIG. 3 is a cross-sectional view showing the continuous step of the wafer mounting process from that of FIG. 2.

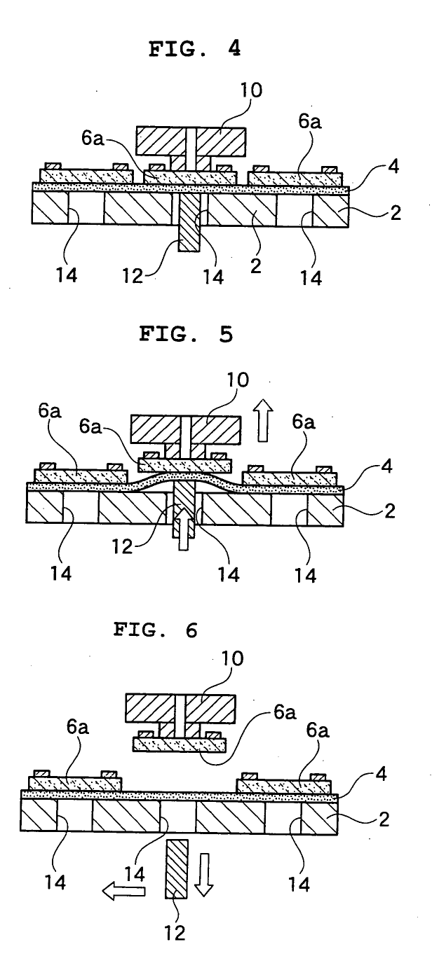

FIG. 4 is a cross-sectional view showing the continuous step of the wafer mounting process from that of FIG. 3.

FIG. 5 is a cross-sectional view showing the continuous step of the wafer mounting process from that of FIG. 4.

FIG. 6 is a cross-sectional view showing the continuous step of the wafer mounting process from that of FIG. 5.

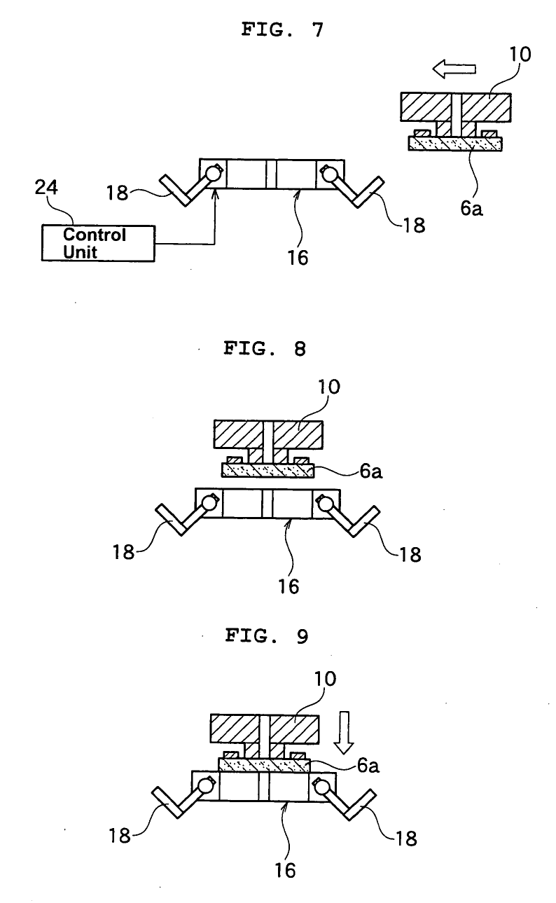

FIG. 7 is a cross-sectional view showing the continuous step of the wafer mounting process from that of FIG. 6.

FIG. 8 is a cross-sectional view showing the continuous step of the wafer mounting process from that of FIG. 7.

FIG. 9 is a cross-sectional view showing the continuous step of the wafer mounting process from that of FIG. 8.

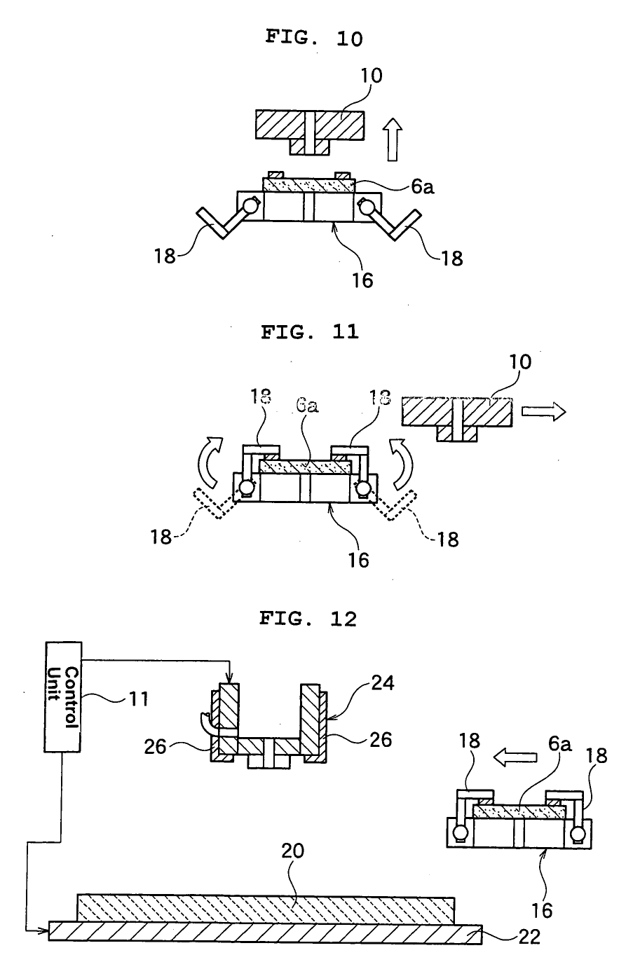

FIG. 10 is a cross-sectional view showing the continuous step of the wafer mounting process from that of FIG. 9.

FIG. 11 is a cross-sectional view showing the continuous step of the wafer mounting process from that of FIG. 10.

FIG. 12 is a cross-sectional view showing the continuous step of the wafer mounting process from that of FIG. 11.

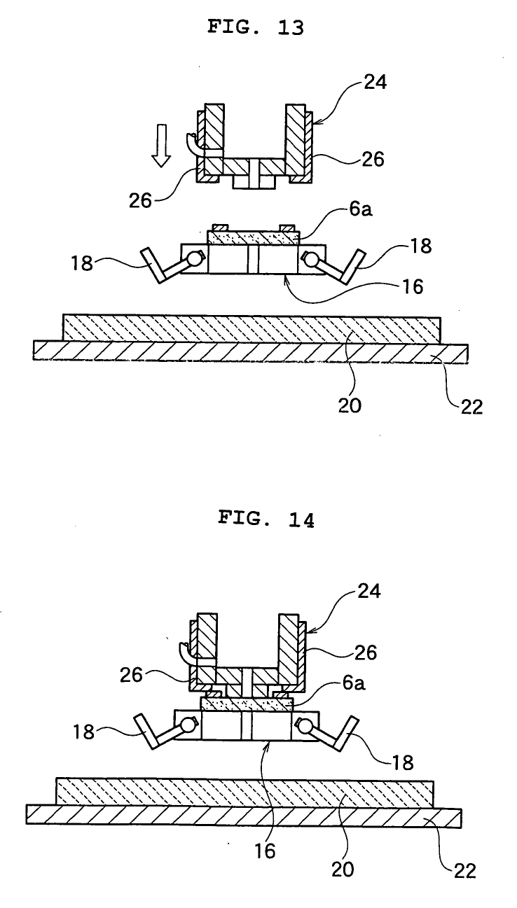

FIG. 13 is a cross-sectional view showing the continuous step of the wafer mounting process from that of FIG. 12.

FIG. 14 is a cross-sectional view showing the continuous step of the wafer mounting process from that of FIG. 13.

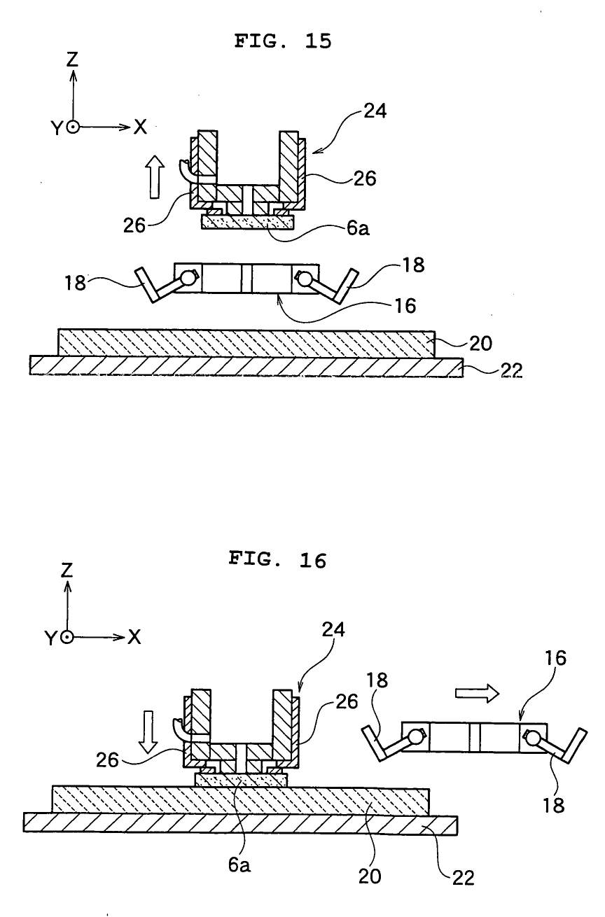

FIG. 15 is a cross-sectional view showing the continuous step of the wafer mounting process from that of FIG. 14.

FIG. 16 is a cross-sectional view showing the continuous step of the wafer mounting process from that of FIG. 15.

As shown in FIG. 1, a mounting device according to one embodiment of the present invention comprises a wafer table 2. On the wafer table 2, a holding sheet 4 formed by adhesive sheet, etc., is placed. On the holding sheet 4, a semiconductor wafer 6, wherein a plurality of predetermined semiconductor element circuits are formed, is detachably held.

As shown in FIG. 2, the mounting device of the present embodiment is provided with a dicer (cutter) 8 as a cutting means on the wafer table 2. The dicer 8 cut the semiconductor wafer 6 on the holding sheet 4 and wafer table 2 to obtain a plurality of chip components 6a. As the chip component 6a, although not particularly limited, in the present embodiment, there may be illustrated an IC chip on which a terminal electrode is formed.

As shown in FIG. 3, the mounting device of the present embodiment comprises a pick-up head 10 for picking up each of the chip components 6a, cut on the holding sheet 4 and wafer table 2, from the wafer table 2. The pick-up head 10 has a suction nozzle structure which allows suction holding of the chip component 6a.

The pick-up head 10 is subject to drive control to be movable in a vertical direction and horizontal direction, and can move back and forth between the later-mentioned carrier table 16 and the wafer table 2 in horizontal direction. The drive control of the pick-up head 10 is performed by a control circuit 11.

Also, on the wafer table 2, a thrusting hole 14 is formed to correspond to the back surface of each chip component 6a, in which an ejector pin 12 is inserted. The ejector pin 12 can be inserted in each thrusting hole 14.

To pick up a specific chip component 6a shown in FIG. 3 from the wafer table 2, first, the ejector pin is inserted from underneath of the thrusting hole 14 corresponding to the back surface (lower surface) of the specific chip component 6a to apply on the lower surface of the holding sheet 4 as shown in FIG. 4. Simultaneously, the pick-up head 10 is pressed on the specific chip component 6a to start suction of the pick-up head.

Next, as shown in FIG. 5, the ejector pin 12 is further pressed up. The pick-up head 10 is simultaneously pushed upward as well as pressing-up motion of the ejector pin. As a result, the chip component 6a is peeled from the holding sheet 4 except for a portion between the ejector pin 12 and chip component 6a.

Then, as shown in FIG. 6, by continuously suction holding the chip component 6a by the pick-up head 10 and pressing the ejector pin 12 downward without changing the position of the pick-up head 10, the holding sheet 4 returns downward, due to restoring force of the holding sheet 4, to the lower direction so as to firmly attach to the wafer table 2. As a result, the chip component 6a is completely peeled from the holding sheet 4.

As shown in FIG. 7, the mounting device of the present embodiment comprises a carrier table 16. The carrier table 16 is provided in a horizontally different position from that of the wafer table 2 shown in FIG. 1 to FIG. 6. The carrier table 16 is movable at least in a horizontal direction and may be movable in a vertical direction as well. A first measuring terminal 18 is rotatably attached to the carrier table 16. Drive control of the carrier table 16 is performed by a control circuit 11.

As shown in FIG. 7 to FIG. 9, the pick-up head 10 suction holds the chip component 6a at the lower side, and horizontally moves to the upside of the carrier table 16. Just above the carrier table 16, the pick-up head 10 moves down to the upper surface of the carrier table 16. Then, while contacting the lower surface of the chip component 6a with the upper surface of the table 16, the head 10 releases the suction holding of the chip component 6a, and as shown in FIG. 10, the head 10 moves upward with regard to the chip component 6a. As a result, the chip component 6a is received on the upper side of the table 16.

As shown in FIG. 11, the pick-up head 10 horizontally moves away from the carrier table 16, and returns to the original pick-up position shown in FIG. 3. During and around the above operation, in the carrier table 16, the first measuring terminal 18 turns and connects to an external terminal of the chip component 6a. The first measuring terminal 18 is connected to an inspection circuit attached in or out of the carrier table 16. The inspection circuit can be built into the control circuit 11.

In the inspection circuit, electric properties, such as inter-terminal current, inter-terminal resistance, inter-terminal capacitance, inter-wiring capacity, inter-wiring resistance, via chain resistance and interlayer capacity, of the chip component can be measured through the first measuring terminal 18. Test of the chip component 6a through the first measuring terminal 18 is performed during transporting the chip component 6a after it is received on the carrier table 16. The test may be performed while the carrier table is at rest, but it is preferable to test while it moves.

As shown in FIG. 12, the mounting device of the present embodiment comprises a substrate table 22, which a mounting substrate 20 is detachably positioned in and fixed to. The substrate table 22 is provided in a horizontally different position from that of the wafer table 2 shown in FIG. 1 to FIG. 6. On the substrate table 22, a mounting head 24, which can suction hold the chip component 6a, is placed to be movable at least in a vertical direction.

Also, the mounting head 24 can relatively move in a horizontal direction with respect to the substrate table 22. Note that the substrate table 22 may be constructed to be movable in a horizontal direction with respect to the mounting head 24. Drive control of the mounting head 24 and substrate table 22 can be performed by the control circuit 11.

A second measuring terminal 26 is attached to the mounting head 24. The second measuring terminal 26 is, as described below, connected to the external terminal of the chip component 6a. The second measuring terminal 26 is connected to an inspection circuit attached into or out of the mounting head 24. The inspection circuit may be built in the control circuit 11.

The inspection circuit may be same as or different from the inspection circuit to which the first measuring terminal is connected. Inspection items tested through the second measuring terminal 26 are preferably different from those tested through the first measuring terminal 18. This is because various tests can be done effectively on the same chip component 6a.

As shown in FIG. 12 to FIG. 13, while the mounting head 24 is superjacent to the substrate table 22, the carrier table moves in a horizontal direction, and is positioned just below the mounting head 24. On the carrier table 16, the chip component 6a is held. While the carrier table 16 is positioned just below the mounting head 24, the first measuring terminal turns, and is disconnected with the chip component 6a.

In this situation, as shown in FIG. 14, the mounting head 24 moves downward, contacts with the upper surface of the chip component 6a held on the upper surface of the carrier table 16, so that the mounting head 24 starts the suction. During and around the above operation, or simultaneously, the carrier table 16 releases the suction holding of the chip component 6a.

Subsequently, as shown in FIG. 15, the mounting head 24 moves upward while keeping the suction holding of the chip component 6a at the lower side, so that the chip component 6a is transferred from the carrier table 16 to the mounting head 24. When the mounting head 24 receives the chip component 6a, the second measuring terminal 26 is automatically connected to the external terminal of the chip component 6a. Then, the carrier table 16 horizontally moves into the position to receive the chip component 6a from the pick-up head 10 shown in FIG. 7 to FIG. 9.

When the carrier table 16 horizontally moves to a position not at all to cause an obstruction for vertical movement of the mounting head 24, the mounting head 24 moves downward in a vertical direction (Z-axis direction) as shown in FIG. 16, so that the lower surface of the chip component 6a, which is suction held at the lower side of the mounting head 24, is applied onto a predetermined position in a horizontal direction (X-Y direction) of the mounting substrate 20 to mount.

While moving the mounting head 24 upward in the Z-axis direction as shown in FIG. 14 to FIG. 15, or while moving the mounting head 24 downward in the Z-axis direction as shown in FIG. 15 to FIG. 16, the chip component 6a is tested through the second measuring terminal 24 as with the first measuring terminal 18.

As shown in FIG. 16, the test of the chip component 6a may be performed after applying the lower surface of the chip component 6a onto the surface of the mounting substrate 20. In this case, it is possible to perform tests such as measurements for checking the connection between the chip component 6a and the mounting substrate 20.

When a defect in the chip component 6a is detected after applying the lower surface of the chip component 6a onto a predetermined position in the horizontal direction (X-Y direction) of the mounting substrate 20 (e.g. in case of not satisfying the mountable conditions), the chip component 6a once contacted with the substrate 20 can be retreated or discarded. Specifically, the chip component 6a is suction held by the mounting head 24, received on the carrier table 16 and transported to a retreating position or a discarding position by the carrier table.

When a defect in the chip component 6a is detected through the second measuring terminal 26 before applying the lower surface of the chip component 6a onto the surface of the mounting substrate 20, the chip component 6a detected as defective can also be retreated or discard as above.

In the mounting device for a chip component according to the present embodiment, the chip component 6a is tested during transportation, resulting in shortening the operating time between cutting the chip component 6a on the wafer table 2 shown in FIG. 2 and mounting the same on the mounting substrate 20 shown in FIG. 16. In addition, by testing the chip component 6a after peeling from the holding sheet 4 shown in FIG. 4 to FIG. 6 during transportation, it is possible to reliably detect the chip component 6a damaged due to peeling from the holding sheet 4. Also, any defective chip component 6a not satisfying the mountable conditions can be eliminated during transportation, so that it is possible to reliably mount only undamaged, non-defective chip components 6a one after another on the mounting substrate 20 shown in FIG. 16.

Also, the mounting device in the present embodiment comprises the pick-up head 10 for receiving the chip component 6a peeled from the holding sheet 4, and the mounting head 24 for mounting the chip component 6a on the mounting substrate 20. Therefore, the receiving operation by the pick-up head 10 and the mounting operation by the mounting head 24 can be concurrently performed, resulting in further shortening of the operating time.

Also, the mounting device of the present embodiment further comprises the carrier table 16 for transporting the chip component 6a received on the pick-up head 10. Therefore, the receiving operation by the pick-up head 10, the mounting operation by the mounting head 24, and the transporting operation by the carrier table 16 can be concurrently performed, so that it is possible to make measurements for testing during the mounting operation or transporting operation of the chip component 6a.

Note that the present invention is not limited to the above-described embodiment, and can be variously modified in the scope of the present invention.

For example, it may be possible to use a stationary table instead of the carrier table 16 shown in FIG. 7 to FIG. 16, and to provide the first measuring terminal 18 in the stationary table, making the mounting head 24 movable horizontally to the receiving position of the chip component 6a from the pick-up head 10 shown in FIG. 8 to FIG. 11. In this case, measurements for testing can be made during temporarily placing of the chip component 6a on the stationary table.

Also, as a peel off means for the chip component 6a from the holding sheet 4 shown in FIG. 3 to FIG. 6, there may be mentioned a thrusting rod and an ultraviolet irradiator instead of the ejector pin 12. In the ultraviolet irradiator, ultraviolet is irradiated to the holding sheet 4 to reduce adhesion of the holding sheet 4, making it easier to peel the chip component 6a from the holding sheet 4.

Further, in the above-identified embodiment, it is preferred to ground the pick-up head 10, the carrier table and the mounting head 24. By grounding these, no static electricity is stored between the chip component 6a and these, so that it is possible to prevent damages due to static electricity on the chip component 6a.

1. A mounting device for a chip component, comprising
a carrier for transporting the chip component, removed from a holding part which holds each of cut chip components, to a mounting substrate to mount the same;
a measuring terminal, provided with at least a part of said carrier, for measuring electric properties of said chip component during transporting; and
a control means for controlling said carrier so as to mount said chip component on said mounting substrate only when a measurement of said chip component determined through said measuring terminal satisfies mountable conditions.

2. The mounting device for a chip component as set forth in claim 1, wherein said carrier comprises a pick-up head for receiving said chip component removed from said holding part; and a mounting head for mounting said chip component on said mounting substrate.

3. The mounting device for a chip component as set forth in claim 2, wherein said carrier further comprises a carrier table for transporting said chip component, received on said pick-up head, to said mounting head.

4. The mounting device for a chip component as set forth in claim 3, wherein said measuring terminal is provided with at least one of said mounting head and said carrier table.

5. The mounting device for a chip component as set forth in claim 2, wherein said carrier further comprises a stationary table for temporarily placing said chip component received on said pick-up head.

6. The mounting device for a chip component as set forth in claim 5, wherein said measuring terminal is provided with at least one of said mounting head and said stationary table.

7. The mounting device for a chip component as set forth in claim 1, wherein
said holding part is a holding sheet for holding individual chip components, and
the mounting device further comprises a peel off means for peeling said chip component from said holding sheet.

8. The mounting device for a chip component as set forth in claim 7, wherein
said holding sheet is attached on a wafer table, and
said peel off means is an ejector pin which is inserted in an opening formed on said wafer table.

9. The mounting device for a chip component as set forth in claim 8, wherein
a cutting means is placed on said wafer table, and
said chip components are obtained by cutting a wafer placed on said holding sheet and wafer table.

10. The mounting device for a chip component as set forth in claim 1, wherein said carrier contacting with said chip component is grounded.
